(19) United States
(12) Patent Application Publication
(10) Pub. No.: US 2004/0032903 A1
(43) Pub. Date: Feb. 19, 2004

(54) Adaptive equaliser

(76) Inventor: Thomas Keller, Great Shelford (GB)

Correspondence Address: BANNER & WITCOFF, LTD., TEN SOUTH WACKER DRIVE, SUITE 3000, CHICAGO, IL, 60606, US

(21) Appl. No.: 10/399,341

(22) PCT Filed: Oct. 16, 2001
(86) PCT No.: PCT/GB01/04602

(30) Foreign Application Priority Data
Oct. 16, 2000 (GB) 0025324.5

(51) Int. Cl. H03K 5/159; H03H 7/30

(52) U.S. Cl. 375/229

(57) ABSTRACT

An equaliser in a receiver for countering multi-path propagation effects in the received signal can be arranged to adjust the maximum path difference used in its equalisation calculations. The limit can be determined by the receiver itself or it may be provided externally. The limit may be determined by observing the maximum path difference in received signals or it may be predetermined in accordance with the propagation environment of the receiver.

The invention relates to channel equalisation techniques used to compensate for multi-path propagation of signals in a telecommunications system.

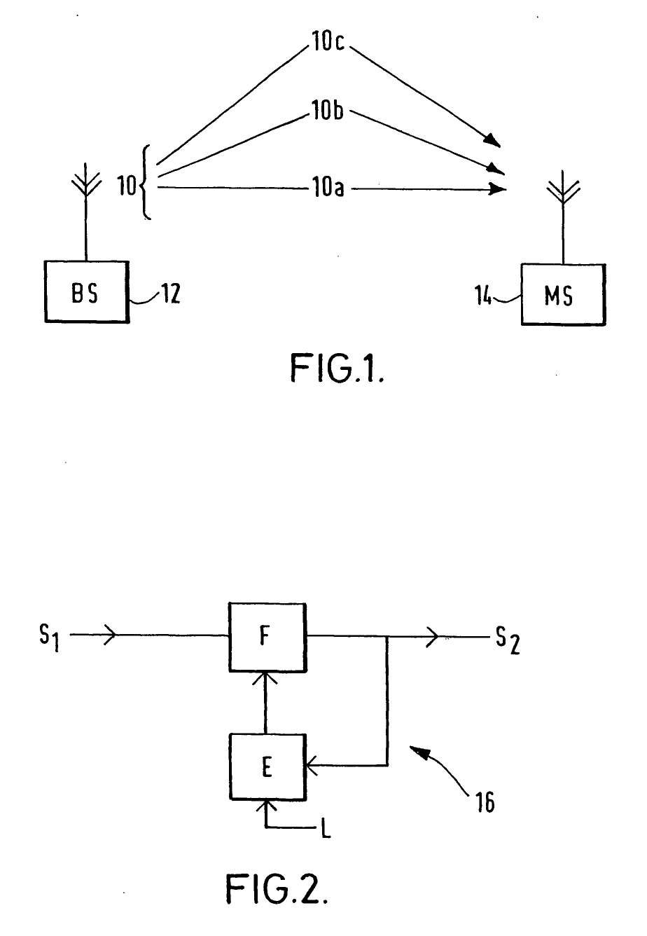

In a wireless telecommunications system, signals sent from a transmitter to a receiver may propagate over several paths to reach the receiver. This situation is illustrated in FIG. 1.

FIG. 1 illustrates a base station 12 which transmits a signal 10 to a mobile telephone 14. The signal 10 reaches the mobile telephone 14 via three different paths 10A to C. Path 10A is direct and is therefore the shortest possible path. Paths 10B and 10C are longer and arise from, for example, the signal 10 being reflected from an obstacle towards the mobile telephone 14.

The signals received along paths 10A to C differ in phase relative to one another by amounts determined by the differences in the length of the paths 10A to C. Signals received along paths 10A to C interfere with one another at the mobile telephone 14. The mobile telephone 14 effectively receives a composite signal which is the sum of the three interfering signals. The composite received signal can be regarded as the result of passing the transmitted signal 10 through a notional filter. To counteract the multi-path interference, the mobile telephone 14 applies a filter to the composite received signal. This filter is arranged to be the inverse of the notional filter representing the interference. The obstacles between the base station 12 and the mobile telephone 14 will vary over time, as will the location of the mobile telephone 14 relative to the base station 12. Therefore, the number of paths to the mobile telephone 14 and the path differences between them will also vary over time. As a result, the compensating filter in the mobile telephone 14 must be adaptive in order to cope with changes in the interference it is trying to counteract.

A synchronisation sequence is embedded in the data transmitted. The synchronisation sequence is known to the receivers in the system. An equaliser in the mobile telephone 14 examines the output of the adaptive filter for the known synchronisation sequence.

The equaliser adjusts the adaptive filter to optimise the recovery of the synchronisation data in the output of the adaptive filter. Thus, the adaptive filter is also optimised for the recovery of the other, and unknown, data from the transmitted signal. In effect, the equaliser equalises the lengths of all the paths to the receiver thus eliminating multi-path interference. Since telecommunication systems must cope with a wide range of propagation channel conditions, the equalisation calculations assume the worst case range of path differences. This means that the equalisation calculation is relatively complex.

One object of the present invention is to provide improved equalisation techniques.

According to one aspect, the invention provides an equaliser for a receiver for ameliorating multi-path effects in received signals, wherein the equaliser is capable of adjusting the path difference limit that it applies in the equalisation process.

According to a related aspect, the invention also provides a method of equalising a received signal to ameliorate multi-path effects in the received signal, comprising adjusting the path difference limit applied in the equalisation process.

Thus, the invention provides a more versatile equalisation technique in which the duration of the equalisation process can be varied by adjusting the path difference limit. For example, the equalisation calculations can be shortened by reducing the maximum path difference used in the calculations.

In a preferred embodiment, the path difference limit is determined according to the environment of the receiver. For example, if the local environment is such that the signal propagation conditions are good, i.e. the differences in the lengths of the paths to the receiver are small, then the path difference limit used in the equalisation calculations can be reduced. The path difference limit may be derived from observed path differences at the receiver. Alternatively, the path difference limit may be derived from path differences observed by another receiver. It is also possible for the limit to be predetermined on the basis of knowledge of the receiver's environment, e.g. setting the path difference limit to small when the environment is cluttered (e.g. urban) or setting the limit to large where the environment is open (e.g. flat countryside).

The invention also extends to a program for implementing the adjustable equaliser.

According to another aspect, the invention also provides a receiver comprising means for determining a path difference limit for signals which it receives and means for providing the limit to other receivers.

According to a related aspect, the invention also provides a method of receiving a signal comprising the step of determining a path difference limit for the received signals and providing the limit to other receivers.

Thus, the invention provides a way of sending information about local signal propagation conditions. Such information can be used by the other receivers to perform equalisation more efficiently.

By way of example only, certain embodiments of the invention will now be described with reference to the accompanying figures, in which:

FIG. 1 is a block diagram illustrating multi-path signal propagation in a telecommunications system; and

FIG. 2 is a block diagram of part of a telecommunications receiver.

Receiver 16 of FIG. 2 is part of a mobile telephone. Receiver 16 comprises an adaptive filter F operating on a signal Si supplied from the antenna of the mobile phone to produce a signal S2. The adaptive filter F cancels the multi-path propagation effects in the signal S1. Equaliser E monitors the signal S2. Equaliser E examines signal S2 for known synchronisation data and optimises adaptive filter F for recovery of the synchronisation data. A limit value L is supplied to the equaliser E. The value L sets the maximum limit of the path difference to be used in the equalisation process. The value L is transmitted to the mobile telephone in the signal S1. The value L is recovered from the signal S2 in a downstream processing unit (not shown).

The limit L is a measure of the maximum path difference encountered in received transmissions by the base station of the cell in which the mobile telephone presently resides. The base station broadcasts the measured limit L to all the mobile telephones in its cell. The mobile telephones use the limit L to optimise their equalisation calculations.

In another embodiment, a base station is arranged to broadcast a predetermined limit L to the mobile telephones in its cell. The predetermined limit L is determined on the basis of the propagation environment of the cell. For example, the limit L is set as a small value where the propagation environment is good (i.e. path differences between received rays are likely to be short). Examples of a good propagation environment include built up urban areas, forested terrain and mountainous regions. Where the propagation environment is poorer (open countryside, for example), the base station is arranged to broadcast a limit L which is larger.

In a yet further embodiment, the mobile telephone measures the maximum path difference of signals which it receives in its present cell and uses that value as the limit L for its equalisation process.

1. An equaliser for a receiver for ameliorating multi-path effects in received signals, wherein the equaliser is capable of adjusting the path difference limit that it applies in the equalisation process.

2. An equaliser according to claim 1, wherein the limit is determined according to the environment of the receiver.

3. An equaliser according to claim 2, wherein the limit is derived from at least one observed path difference.

4. An equaliser according to claim 3, wherein at least one observed path difference is observed by the receiver.

5. An equaliser according to claim 3 or 4, wherein at least one observed path difference is observed by another receiver.

6. An equaliser according to claim 2, wherein the limit is predetermined on the basis of knowledge of the receiver's environment.

7. A method of equalising a received signal to ameliorate multi-path effects in the received signal, comprising adjusting the path difference limit applied in the equalisation process.

8. A method according to claim 7, wherein the limit is determined according to the environment in which reception occurs.

9. A method according to claim 8, wherein the limit is derived from at least one observed path difference.

10. A method according to claim 9, wherein at least one observed path difference is observed in the course of receiving signals.

11. A method according to claim 9 or 10, wherein at least one observed path difference is observed by another receiver.

12. A method according to claim 8, wherein the limit is predetermined on the basis of knowledge of the receiver's environment.

13. A program for carrying out the method of any one of claims 7 to 12.

14. A base station, a mobile telephone, or a mobile radio comprising a receiver according to any one of claims 1 to 6.

15. A receiver comprising means for determining a path difference limit for signals which it receives and means for providing the limit to other receivers.

16. A method of receiving a signal comprising the step of determining a path difference limit for the received signals and providing the limit to other receivers.

17. A method of receiving a signal substantially as hereinbefore described with reference to the accompanying figures.

18. A method of equalising a received signal substantially as hereinbefore described with reference to the accompanying figures.

19. A equaliser substantially as hereinbefore described with reference to the accompanying figures.

20. A receiver substantially as hereinbefore described with reference to the accompanying figures.
